(19) United States
(12) Patent Application Publication
(10) Pub. No.: US 2018/0083589 A1
(43) Pub. Date: Mar. 22, 2018

(54) FACE-TO-FACE MULTIPLEXER CIRCUIT LAYOUT

(71) Applicant: QUALCOMM Incorporated, San Diego, CA (US)

(72) Inventors: Changhan Hobie YUN, San Diego, CA (US); Chengjie ZUO, San Diego, CA (US); David Francis BERDY, San Diego, CA (US); Mario Francisco VELEZ, San Diego, CA (US); Niranjan Sunil MUDAKATTE, San Diego, CA (US); Jonghae KIM, San Diego, CA (US)

(21) Appl. No.: 15/273,596

(22) Filed: Sep. 22, 2016

(51) Int. Cl. H03H 7/46; H03H 7/01; H03H 1/00; H03H 3/00

(52) U.S. Cl. CPC H03H 7/0138; H03H 7/0115; H03H 2007/013; H03H 3/00; H03H 2001/0078; H03H 1/00

(57) ABSTRACT

The present disclosure provides circuits and methods for fabricating circuits. A circuit may include a first insulator, a second insulator, a first subset of circuit elements disposed on a bottom surface of the first insulator, a second subset of circuit elements disposed on a top surface of the second insulator, one or more conductive couplings disposed between the first subset of circuit elements and the second subset of circuit elements.

### FIELD

Aspects of this disclosure relate generally to wireless communication devices, and more particularly to multiplexer circuits having a face-to-face (F2F) circuit layout.

### BACKGROUND

Wireless communication devices conventionally include a large number of circuits, including, for example, one or more multiplexers. Generally, multiplexers may separate an incoming signal or an outgoing signal into a plurality of distinct frequency bands. For example, a wireless communication device may include a multiplexer that separates an incoming signal or an outgoing signal into two bands associated with different bandwidths. The different bandwidths may be respectively centered on, for example, a first frequency and a second frequency, wherein the first frequency is higher than the second frequency. These bandwidths may be referred to as a high-frequency band and a low-frequency band, respectively.

Each circuit may include passive components, for example, capacitors and inductors. In a multiplexer, for example, the passive components may be configured to separate the incoming signal or the outgoing signal into high-frequency components (i.e., signal components within the high-frequency band) and low-frequency components (i.e., signal components within the low-frequency band). A wireless communication device may include a plurality of multiplexers, for example, a first multiplexer for wireless local area network (WLAN) connectivity (for example, in accordance with a Wi-Fi connection protocol) and a second multiplexer for wireless wide area network (WWAN) connectivity (for example, in accordance with a Long-Term Evolution, or LTE connection protocol).

There is a need in the field of wireless communication devices for smaller circuits, especially multiplexers, which tend to have large passive components (such as, for example, inductors).

There is also a need to improve the performance of the circuits. For example, in some existing multiplexer arrangements, the relative proximity of two inductors may cause cross-talk, thereby distorting the signal as it passes through the multiplexer.

### SUMMARY

In one aspect, the present disclosure provides a circuit apparatus. The circuit apparatus may include a first insulator, a second insulator, a first subset of circuit elements disposed on a bottom surface of the first insulator, a second subset of circuit elements disposed on a top surface of the second insulator, and one or more conductive couplings disposed between the first subset of circuit elements and the second subset of circuit elements.

In another aspect, the present disclosure provides a method of manufacturing a circuit apparatus. The method may include providing a first insulator, providing a second insulator, disposing a first subset of circuit elements on a bottom surface of the first insulator, disposing a second subset of circuit elements on a top surface of the second insulator, and providing one or more conductive couplings disposed between the first subset of circuit elements and the second subset of circuit elements.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the invention, and in which:

FIG. 1 generally illustrates a schematic diagram of a circuit in accordance with an aspect of the disclosure.

FIG. 2 generally illustrates a conventional planar circuit layout for implementing a multiplexer.

FIG. 3A generally illustrates a face-to-face circuit layout for implementing a multiplexer in accordance with an aspect of the disclosure.

FIG. 3B generally illustrates a nested portion of the face-to-face circuit layout of FIG. 3A.

FIG. 3C generally illustrates a nesting portion of the face-to-face circuit layout of FIG. 3A.

FIG. 4 generally illustrates a side view of a face-to-face circuit layout for implementing a multiplexer in accordance with another aspect of the disclosure.

FIG. 5A generally illustrates a schematic diagram of a circuit in accordance with an aspect of the disclosure.

FIG. 5B generally illustrates the effects of mutual inductance in the circuit of FIG. 5A.

FIG. 6 generally illustrates a flow diagram for manufacturing a multiplexer having a face-to-face circuit layout in accordance with yet another aspect of the disclosure.

FIG. 7 generally illustrates a block diagram showing an exemplary wireless communication system in which aspects of the disclosure may be advantageously employed.

FIG. 8 generally illustrates a block diagram illustrating a design workstation used for circuit, layout, and logic design of the disclosed circuits.

### DETAILED DESCRIPTION

Aspects of the disclosure are disclosed in the following description and related drawings directed to specific aspects of the disclosure. Alternate aspects may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

As used herein, the term “vertical” is generally defined with respect to a surface of a substrate or carrier upon which a semiconductor package is formed. The substrate or carrier will generally define a “horizontal” plane, and a vertical direction approximates a direction that is roughly orthogonal to the horizontal plane.

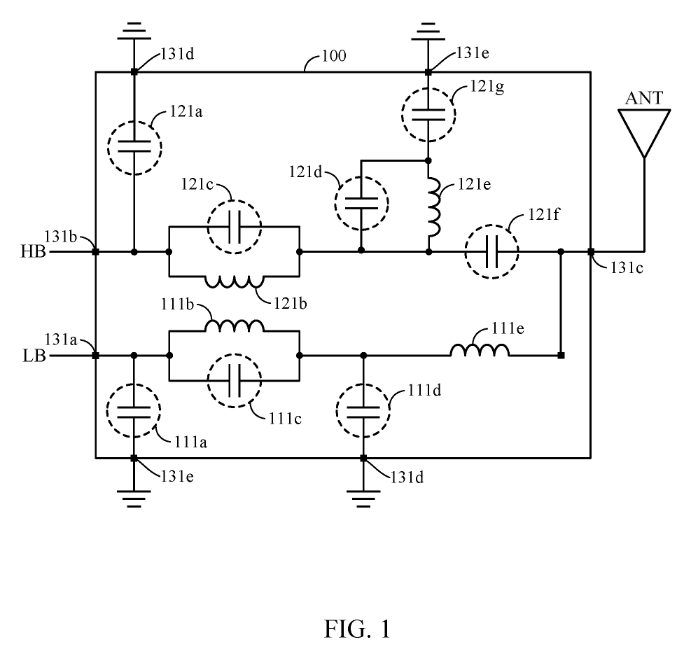

FIG. 1 generally illustrates a schematic diagram of a circuit 100 in accordance with an aspect of the disclosure. The circuit 100 may be, for example, a multiplexer.

The circuit 100 may include a first subset of circuit elements 111a-111e (which may be referred to collectively as first subset of circuit elements 111) and a second subset of circuit elements 121a-121g (which may be referred to collectively as second subset of circuit elements 121). The first subset of circuit elements 111 and the second subset of circuit elements 121 may each include a plurality of passive electrical components (for example, capacitors and inductors) coupled to one another via conductive traces. The conductive traces may be configured to create direct electrical couplings between various components of the circuit 100.

The circuit 100 may further include a plurality of terminals 131a-131e. As depicted in FIG. 1, the plurality of terminals 131a-131e may include a LB terminal 131a (wherein “LB” stands for low-frequency band), a HB terminal 131b (wherein “HB” stands for high-frequency band), and an antenna terminal 131c. The plurality of terminals 131 may further include one or more ground terminals, for example, a first ground terminal 131d and a second ground terminal 131e.

As further depicted in FIG. 1, the LB terminal 131a may be coupled to the antenna terminal 131c and one or more ground terminals via the first subset of circuit elements 111. In particular, the LB terminal 131a may be coupled via conductive trace to a first LB capacitor 111a, a first LB inductor 111b, and a second LB capacitor 111c. The first LB capacitor 111a may be coupled via conductive trace to the one or more ground terminals, for example, second ground terminal 131e. The first LB inductor 111b and the second LB capacitor 111c may be disposed in parallel and may be coupled via conductive trace to a third LB capacitor 111d and a second LB inductor 111e. The third LB capacitor 111d may be coupled via conductive trace to the one or more ground terminals, for example, first ground terminal 131d. The second LB inductor 111e may be coupled via conductive trace to the antenna terminal 131c.

It will be understood that although the first subset of circuit elements 111 may include one or more of the first LB capacitor 111a, the first LB inductor 111b, the second LB capacitor 111c, the third LB capacitor 111d, and the second LB inductor 111e, as depicted in FIG. 1, the first subset of circuit elements 111 may include fewer components than appear in FIG. 1, or more components apart from those listed.

The HB terminal 131b may be coupled to the antenna terminal 131c and one or more ground terminals via the second subset of circuit elements 121. In particular, the HB terminal 131b may be coupled via conductive trace to a first HB capacitor 121a, a first HB inductor 121b, and a second HB capacitor 121c. The first HB capacitor 121a may be coupled via conductive trace to the one or more ground terminals, for example, first ground terminal 131d. The first HB inductor 121b and the second HB capacitor 121c may be disposed in parallel and may be coupled via conductive trace to a third HB capacitor 121d, a second HB inductor 121e, and a fourth HB capacitor 121f. The third HB capacitor 121d and the second HB inductor 121e may be disposed in parallel and may be coupled via conductive trace to a fifth HB capacitor 121g. The fifth HB capacitor 121g may be coupled to the one or more ground terminals, for example, the second ground terminal 131e. The fourth HB capacitor 121f may be coupled via conductive trace to the antenna terminal 131c.

It will be understood that although the second subset of circuit elements 121 may include one or more of the first HB capacitor 121a, the first HB inductor 121b, the second HB capacitor 121c, the third HB capacitor 121d, the second HB inductor 121e, the fourth HB capacitor 121f, and the fifth HB capacitor 121g, as depicted in FIG. 1, the second subset of circuit elements 121 may include fewer components than appear in FIG. 1, or more components apart from those listed.

In some implementations, the first subset of circuit elements 111 may be configured to filter a signal received from either the LB terminal 131a or the antenna terminal 131c. Moreover, the second subset of circuit elements 121 may be configured to filter a signal received from either the HB terminal 131b or the antenna terminal 131c. The filtering performed by the first subset of circuit elements 111 and/or the second subset of circuit elements 121 may reduce signal components that are outside of a particular frequency bandwidth. For example, the first subset of circuit elements 111 may reduce signal components that are outside of a LB frequency bandwidth centered around a first frequency, and the second subset of circuit elements 121 may reduce signal components that are outside of a HB frequency bandwidth centered around a second frequency, wherein the second frequency is higher than the first frequency. The LB frequency bandwidth and the HB frequency bandwidth may be non-overlapping. Moreover, the first subset of circuit elements may include a first inductor and a first capacitor and the second subset of circuit elements may include a second inductor having a lower inductance than the first inductor and a second capacitor having a lower capacitance than the first capacitor.

The circuit 100 may be coupled to one or more processors, one or more memories, or one or more other components of a wireless communication device via the LB terminal 131a and/or the HB terminal 131b. The circuit 100 may be a multiplexer that is coupled to an antenna via the antenna terminal 131c and coupled to a ground of a wireless communication device via the one or more ground terminals, for example, the first ground terminal 131d and/or the second ground terminal 131e.

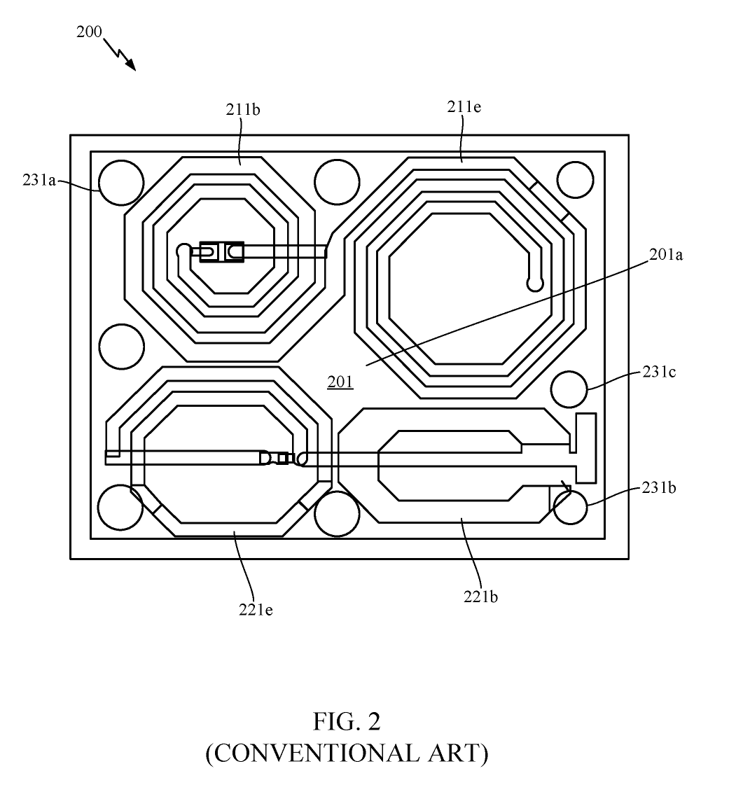

FIG. 2 generally illustrates a conventional planar circuit layout 200 for implementing a circuit, for example, a multiplexer. The circuit depicted in FIG. 2 may have some components that are analogous to the components depicted in FIG. 1. For example, the circuit depicted in FIG. 2 may include a first subset of circuit elements that include a first LB inductor 211b and a second LB inductor 211e. The first LB inductor 211b and the second LB inductor 211e may be analogous to the first LB inductor 111b and the second LB inductor 111e depicted in FIG. 1, respectively. The circuit depicted in FIG. 2 may further include a second subset of circuit elements that include a first HB inductor 221e and a second HB inductor 221b. The first HB inductor 221e and the second HB inductor 221b may be analogous to the second HB inductor 121e and the first HB inductor 121b depicted in FIG. 1, respectively. The circuit depicted in FIG. 2 may further include a LB terminal 231a, a HB terminal 231b, and an antenna terminal 231c. It will be understood that the various components depicted in FIG. 2 may be analogous in some respects to the various terminals and inductors depicted in FIG. 1.

As will be understood from FIG. 2, the first LB inductor 211b, the second LB inductor 211e, the first HB inductor 221e, and the second HB inductor 221b are each implemented as spiral inductors fabricated on a first planar surface 201a of a substrate 201. The area of the first planar surface 201a must be large enough to accommodate each of the spiral inductors depicted in FIG. 2. However, there is a need in the field of wireless communication devices to reduce the size of multiplexers, which tend to include relatively large components (such as, for example, the inductors depicted in FIG. 2). Accordingly, new circuit layouts are required that reduce the area of, for example, the first planar surface 201a of the substrate 201.

As will be further understood from FIG. 2, the various components may be disposed in close proximity to one another. For example, the first LB inductor 211b is relatively proximate to the first HB inductor 221e and the second LB inductor 211e is relatively proximate to the second HB inductor 221b. As a result, the close proximity of the components may cause, for example, cross-talk, thereby distorting the signal as it passes through the multiplexer. Accordingly, new circuit layouts that reduce the proximity between components are desirable.

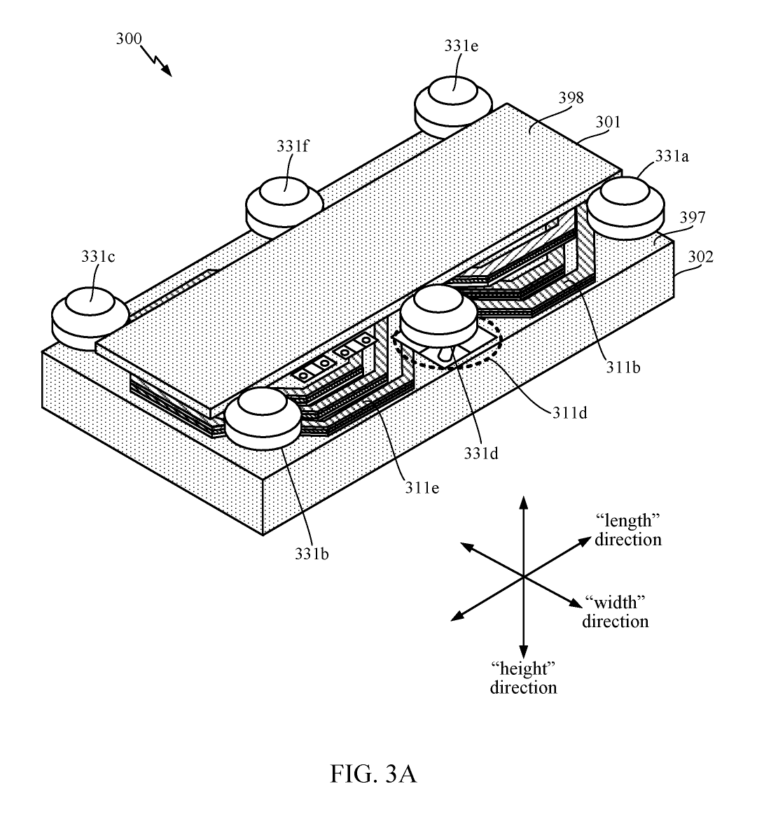

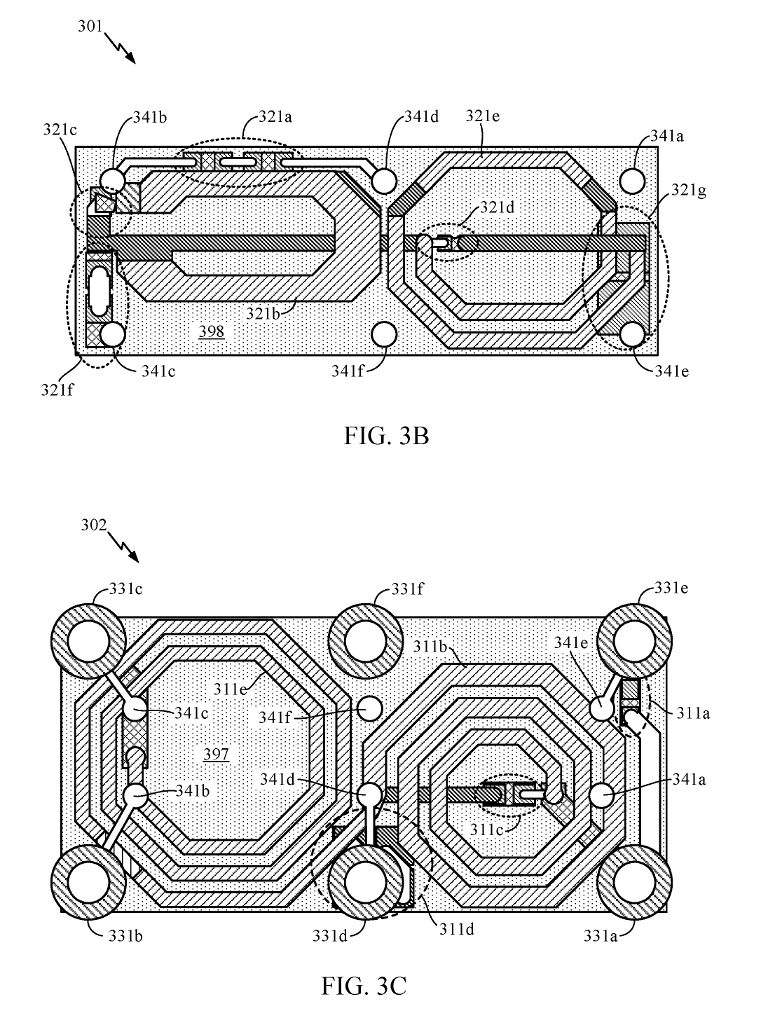

FIGS. 3A-3C generally illustrate a face-to-face (F2F) circuit layout for implementing a circuit 300 in accordance with aspects of the disclosure. The circuit 300 may be, for example, a multiplexer. FIG. 3A generally illustrates the circuit 300 as a whole, including a nested portion 301 and a nesting portion 302 provided in a F2F arrangement. FIG. 3B generally illustrates the nested portion 301 of the face-to-face circuit layout of FIG. 3A, whereas FIG. 3C generally illustrates the nesting portion 302 of the face-to-face circuit layout of FIG. 3A.

The circuit 300 may be an implementation of the circuit 100 shown in a schematic view in FIG. 1. As shown in FIG. 3C, the nesting portion 302 of the circuit 300 may include a first subset of circuit elements 311a-311e (which may be referred to collectively as first subset of circuit elements 311) analogous to the first subset of circuit elements 111a-111e depicted in FIG. 1. As shown in FIG. 3B, the nested portion 301 of the circuit 300 may include a second subset of circuit elements 321a-321g (which may be referred to collectively as second subset of circuit elements 321) analogous to the second subset of circuit elements 121a-121g depicted in FIG. 1. The first subset of circuit elements 311 and the second subset of circuit elements 321 may each include a plurality of passive electrical components (for example, capacitors and inductors) coupled to one another via conductive traces. The conductive traces may be configured to create direct electrical couplings between various components of the circuit 300.

As shown in FIG. 3A and FIG. 3C, the nesting portion 302 of the circuit 300 may further include a plurality of terminals 331a-331e analogous to the plurality of terminals 131a-131e. As depicted in FIG. 3, the plurality of terminals 331a-331e may include a LB terminal 331a (wherein “LB” stands for low-frequency band), a HB terminal 331b (wherein “HB” stands for high-frequency band), and an antenna terminal 331c. The plurality of terminals 331a-331e may further include one or more ground terminals, for example, a first ground terminal 331d and a second ground terminal 331e. The plurality of terminals 331a-331e may further include a dummy terminal 331f. In some implementations, the dummy terminal 331f may be omitted. In other implementations, the dummy terminal 331f may duplicate the function of another of the plurality of terminals 331a-331e and/or provide structural support for the F2F circuit layout of the circuit 300.

As further depicted in FIG. 3C, the LB terminal 331a may be coupled to the antenna terminal 331c and one or more ground terminals via the first subset of circuit elements 311. In particular, the LB terminal 331a may be coupled via conductive trace to a first LB capacitor 311a, a first LB inductor 311b, and a second LB capacitor 311c. The first LB capacitor 311a may be coupled via conductive trace to the one or more ground terminals, for example, second ground terminal 331e. The first LB inductor 311b and the second LB capacitor 311c may be disposed in parallel and may be coupled via conductive trace to a third LB capacitor 311d and a second LB inductor 311e. The third LB capacitor 311d may be coupled via conductive trace to the one or more ground terminals, for example, first ground terminal 331d. The second LB inductor 311e may be coupled via conductive trace to the antenna terminal 331c. It will be understood that although the first subset of circuit elements 311 may include one or more of the first LB capacitor 311a, the first LB inductor 311b, the second LB capacitor 311c, the third LB capacitor 311d, and the second LB inductor 311e, as depicted in FIG. 3C, the first subset of circuit elements 311 may include fewer components than appear in FIG. 3C, or more components apart from those listed.

Also depicted in FIG. 3C is a plurality of F2F couplings 341a-341f (which may be referred to collectively as plurality of F2F couplings 341). The plurality of F2F couplings 341 may be configured to couple components of the nesting portion 302 to the plurality of terminals 331a-331e. Additionally or alternatively, the plurality of F2F couplings 341 may be configured to provide structural support for the nested portion 301 with respect to the nesting portion 302. Accordingly, the plurality of F2F couplings 341 are depicted in both FIG. 3B and FIG. 3C. The plurality of F2F couplings 341 may be implemented as, for example, solder balls, flip chip bumps, or any other suitable material or arrangement.

As will be understood from FIG. 3C, the F2F coupling 341b may be coupled to the HB terminal 331b, the F2F coupling 341c may be coupled to the antenna terminal 331c, the F2F coupling 341d may be coupled to the ground terminal 331d, and the F2F coupling 341e may be coupled to the second ground terminal 331e. The F2F coupling 341a and the F2F coupling 341f may be dummy couplings that are not coupled to any components of the circuit 300. Accordingly, the F2F coupling 341a and the F2F coupling 341f may optionally be omitted, or alternatively, may be provided for redundancy, or for structural support of the nested portion 301 with respect to the nesting portion 302.

As will be understood from FIGS. 3B-3C, the F2F coupling 341b may be coupled to the HB terminal 331b (provided on the nesting portion 302), as well as the first HB capacitor 321a, the first HB inductor 321b, and the second HB capacitor 321c (provided on the nested portion 301). Moreover, the F2F coupling 341c may be coupled to the antenna terminal 331c (provided on the nesting portion 302), as well as the fourth HB capacitor 321f (provided on the nested portion 301). Moreover, the F2F coupling 341d may be coupled to the ground terminal 331d (provided on the nesting portion 302), as well as the first HB capacitor 321a (provided on the nested portion 301). Moreover, the F2F coupling 341e may be coupled to the second ground terminal 331e (provided on the nesting portion 302), as well as the fifth HB capacitor 321g (provided on the nested portion 301).

As will be understood from FIG. 3B, the first HB inductor 321b and the second HB capacitor 321c may be disposed in parallel and may be coupled via conductive trace to a third HB capacitor 321d, a second HB inductor 321e, and a fourth HB capacitor 321f. The third HB capacitor 321d and the second HB inductor 321e may be disposed in parallel and may be coupled via conductive trace to the fifth HB capacitor 321g.

It will be understood that although the second subset of circuit elements 321 may include one or more of the first HB capacitor 321a, the first HB inductor 321b, the second HB capacitor 321c, the third HB capacitor 321d, the second HB inductor 321e, the fourth HB capacitor 321f, and the fifth HB capacitor 321g, as depicted in FIG. 3B, the second subset of circuit elements 321 may include fewer components than appear in FIG. 3B, or more components apart from those listed.

Returning to FIG. 3A, it will be understood that the nesting portion 302 may be disposed on the nested portion 301 to form the circuit 300. In particular, the nesting portion 302 may include a first insulator 397 and the nested portion 301 may include a second insulator 398. The circuit 300 is depicted in FIG. 3A in an “upside-down” configuration in which the first subset of circuit elements 311 and the plurality of terminals 331a-331e may be disposed on a “bottom” surface of the first insulator 397 and the second subset of circuit elements 321 may be disposed on a “top” surface of the second insulator 398. It will be understood that terms such as “top” versus “bottom”, “up” versus “down”, “length” versus “width” versus “height”, etc., are relative terms used strictly in relation to one another, and do not express or imply any relation with respect to gravity, a manufacturing device used to manufacture the circuit 300, or to some other device to which the circuit 300 is coupled, mounted, etc.

Accordingly, the first subset of circuit elements 311 and the second subset of circuit elements 321 are disposed in a F2F arrangement, as noted above, in that the first subset of circuit elements 311 are “facing up” (with respect to FIG. 3A) and the second subset of circuit elements 321 are “facing down” (with respect to FIG. 3A). The plurality of F2F couplings 341 (not shown in FIG. 3A) may be disposed between the first subset of circuit elements 311 and the second subset of circuit elements 321. As noted above, the plurality of F2F couplings 341 may provide coupling between the plurality of terminals 331a-331e and the second subset of circuit elements 321 and/or structural support for the nested portion 301 with respect to the nesting portion 302.

The first insulator 397 and the second insulator 398 may each be substantially rectangular. The insulators 397, 398 may respectively have a length, a width, and a height (wherein a height may also be referred to as a “thickness”). The insulators 397, 398 may be “flat” in that their respective lengths and widths are substantially greater than their heights. Moreover, the height of the first insulator 397 and/or the second insulator 398 may be greater than and/or substantially greater than the height of the components thereon (for example, the first subset of circuit elements 311 and the second subset of circuit elements 321, respectively). In some implementations, the first insulator 397 may be thicker and/or substantially thicker than the second insulator 398 (as is shown in FIG. 3A). Moreover, as will be discussed in greater detail below, the respective heights of the plurality of terminals 331a-331e may be greater than the collective heights of the second insulator 398 and the plurality of F2F couplings 341.

In some implementations, the respective lengths of the insulators 397, 398 may be greater than the respective widths of the insulators 397, 398. As will be understood from FIG. 3A, the respective lengths of the insulators 397, 398 may be equal and/or substantially equal, whereas the width of the first insulator 397 may be greater and/or substantially greater than the width of the second insulator 398. The relatively smaller width of the second insulator 398 may enable the nested portion 301 to be “nested” between the plurality of terminals 331a-331e disposed on the nesting portion 302. For example, the width of the nesting portion 302 may be greater than or equal to the combined width of the first insulator 397 and one terminal of the plurality of terminals 331a-331e. As another example (as shown in FIG. 3A), the width of the nesting portion 302 may be greater than or equal to the combined width of the first insulator 397 and two terminals of the plurality of terminals 331a-331e. Moreover, the height of the plurality of terminals 331a-331e may be selected such that they extend beyond the nested portion 301 in a height direction, thereby enabling the nesting portion 302 to be coupled to, for example, a printed circuit board (PCB). The insulators 397, 398 may be formed of any suitable material. For example, the first insulator 397 and/or the second insulator 398 may include glass.

In some implementations, the first subset of circuit elements 311a-e may be configured to filter a signal received from either the LB terminal 331a or the antenna terminal 331c. Moreover, the second subset of circuit elements 321a-g may be configured to filter a signal received from either the HB terminal 331b or the antenna terminal 331c. The filtering performed by the first subset of circuit elements 311a-e and/or the second subset of circuit elements 321a-g may reduce signal components that are outside of a particular frequency bandwidth. For example, the first subset of circuit elements 311a-e may reduce signal components that are outside of a LB frequency bandwidth centered around a first frequency, and the second subset of circuit elements 321a-g may reduce signal components that are outside of a HB frequency bandwidth centered around a second frequency, wherein the second frequency is higher than the first frequency. The LB frequency bandwidth and the HB frequency bandwidth may be non-overlapping.

The circuit 300 may be coupled to one or more processors, one or more memories, or one or more other components of a wireless communication device via the LB terminal 331a and/or the HB terminal 331b. The circuit 300 may be coupled to an antenna via the antenna terminal 331c and may be coupled to a ground of a wireless communication device via the ground terminal 331d. The plurality of terminals 331a-d may be the only components in the circuit 300 configured to transfer current from the circuit 300 to the one or more processors, one or more memories, antenna, or one or more other components of a wireless communication device (or vice-versa). The plurality of terminals 33 la-d may be implemented using solder balls. The solder balls may be BGA solder balls arranged to complement a ball grid array (BGA). Moreover, the plurality of F2F couplings 341 may be the only components in the circuit 300 configured to transfer current from the first subset of circuit elements 311a-e to the second subset of circuit elements 321a-g (or vice-versa).

In some implementations, the plurality of terminals 331a-d may conform to a particular footprint. For example, the footprint of the circuit 300 may have an area that is substantially equal to an area of the first insulator 397. Moreover, the footprint of the circuit 300 may be substantially rectangular. The rectangular footprint may have two long sides with respective lengths substantially equal to x millimeters and two short sides with respective lengths equal to y millimeters. For example, the rectangular footprint may be 2.5 millimeters by 2.0 millimeters, 2.0 millimeters by 1.25 millimeters, 1.6 millimeters by 0.8 millimeters, or any other suitable footprint. In some implementations (such as the implementation depicted in FIGS. 3A-3C, the first insulator 397 may be a solid volume having no holes or through vias. Similarly, the second insulator 398 may be a solid volume having no holes or through vias.

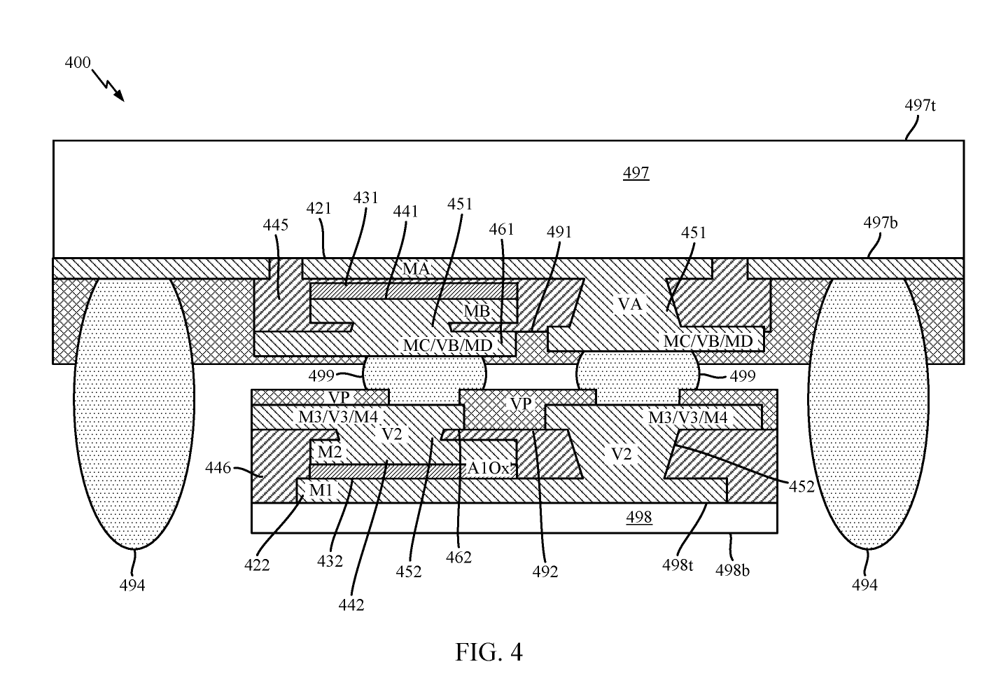

FIG. 4 generally illustrates a side view of a F2F circuit layout for implementing a circuit 400 in accordance with another aspect of the disclosure. The circuit 400 may be analogous to the circuit 300 depicted in FIG. 3. However, whereas the circuit 300 is depicted from an “upside-down” perspective (as noted above), the circuit 400 is depicted in a “right-side up” perspective. However, as noted above, terms such as “top” versus “bottom”, “up” versus “down”, “length” versus “width” versus “height”, etc., are relative terms used strictly in relation to one another, and do not express or imply any relation with respect to gravity, a manufacturing device used to manufacture the circuit 400, or to some other device to which the circuit 400 is coupled, mounted, etc.

The circuit 400 may be, for example, a multiplexer. The circuit 400 may include a first insulator 497 having a first insulator top surface 497t and a first insulator bottom surface 497b. The circuit 400 may further include a second insulator 498 having a second insulator top surface 498t and a second insulator bottom surface 498b.

The first insulator bottom surface 497b may have a first inner conductive layer 421 disposed thereon and the second insulator top surface 498t may have a second inner conductive layer 422 disposed thereon. The first inner conductive layer 421 may form a terminal of one or more capacitors analogous to, for example, the first LB capacitor 311a, the second LB capacitor 311c, and/or the third LB capacitor 311d. The second inner conductive layer 422 may form a terminal of one or more capacitors analogous to, for example, the first HB capacitor 321a, the second HB capacitor 321c, the third HB capacitor 321d, the fourth HB capacitor 321f, and/or the fifth HB capacitor 321g. The first inner conductive layer 421 and the second inner conductive layer 422 may include any suitable material, for example, copper. The first inner conductive layer 421 and the second inner conductive layer 422 may have any suitable thickness, for example, two micrometers.

The first inner conductive layer 421 may have a first dielectric layer 431 disposed thereon and the second inner conductive layer 422 may have a second dielectric layer 432 disposed thereon. The first dielectric layer 431 may form a dielectric layer of one or more capacitors analogous to, for example, the first LB capacitor 311a, the second LB capacitor 311c, and/or the third LB capacitor 311d. The second dielectric layer 432 may form a dielectric layer of one or more capacitors analogous to, for example, the first HB capacitor 321a, the second HB capacitor 321c, the third HB capacitor 321d, the fourth HB capacitor 321f, and/or the fifth HB capacitor 321g. The first dielectric layer 431 and the second dielectric layer 432 may include any suitable material, for example, aluminum oxide and/or silicon nitride.

The first dielectric layer 431 may have a first middle conductive layer 441 disposed thereon and the second dielectric layer 432 may have a second middle conductive layer 442 disposed thereon. The first middle conductive layer 441 may form a terminal of one or more capacitors analogous to, for example, the first LB capacitor 311a, the second LB capacitor 311c, and/or the third LB capacitor 311d. The second middle conductive layer 442 may form a terminal of one or more capacitors analogous to, for example, the first HB capacitor 321a, the second HB capacitor 321c, the third HB capacitor 321d, the fourth HB capacitor 321f, and/or the fifth HB capacitor 321g. The first middle conductive layer 441 and the second middle conductive layer 442 may include any suitable material, for example, copper. The first middle conductive layer 441 and the second middle conductive layer 442 may have any suitable thickness, for example, two micrometers, and may be significantly less thick than the first insulator 497.

The first inner conductive layer 421, the first dielectric layer 431, and the first middle conductive layer 441 may be at least partially embedded in a first middle insulator 445. The first inner conductive layer 421, the first dielectric layer 431, and the first middle conductive layer 441 may be at least partially embedded in a second middle insulator 446. The first middle insulator 445 and the second middle insulator 446 may include any suitable material, for example, laminate.

The first middle insulator 445 may have one or more first vias 451 formed therein and the second middle insulator 446 may have one or more second vias 452 formed therein. The one or more first vias 451 may be electrically conductive and may be coupled to the first inner conductive layer 421 and/or the first middle conductive layer 441. The one or more second vias 452 may be electrically conductive and may be coupled to the second inner conductive layer 422 and/or the second middle conductive layer 442.

The first middle insulator 445 may have a first outer conductive layer 461 disposed thereon and the second middle insulator 446 may have a second outer conductive layer 462 formed thereon. The first outer conductive layer 461 may be in contact with one or more of the one or more first vias 451 and the second outer conductive layer 462 may be in contact with one or more of the one or more second vias 452. Portions of the first outer conductive layer 461 and the second outer conductive layer 462 may take the shape of spiral inductors. For example, the first LB inductor 311b and/or the second LB inductor 311e depicted in FIG. 3C may be formed of the first outer conductive layer 461 and the first HB inductor 321b and/or the second HB inductor 321e depicted in FIG. 3B may be formed of the second outer conductive layer 462.

Each of the first outer conductive layer 461 and the second outer conductive layer 462 may include three sublayers, for example, an inner conductive sublayer, an insulative sublayer having vias therethrough, and an outer conductive sublayer.

A first outer insulating layer 491 may be disposed on the first inner conductive layer 421, the first outer conductive layer 461, and/or the first middle insulator 445 and a second outer insulating layer 492 may be disposed on the second outer conductive layer 462 and/or the second middle insulator 446. The first outer insulating layer 491 and/or the second outer insulating layer 492 may be patterned so as to expose one or more portions of the first outer conductive layer 461 and/or the second outer conductive layer 462, respectively. The first outer insulating layer 491 and/or the second outer insulating layer 492 may include solder-resistant material.

One or more solder balls 494 may be disposed in a ball grid array (BGA) in and/or on the first outer insulating layer 491. The one or more solder balls 494 may be analogous to, for example, the plurality of terminals 331a-d depicted in FIG. 3. The one or more solder balls 494 may be placed into contact with the first inner conductive layer 421. The one or more solder balls may contact the first inner conductive layer 421 at an exposed portion of the first inner conductive layer 421, for example, at a portion exposed through the first outer insulating layer 491. The one or more solder balls 494 may be configured to couple the circuit 400 to another device, for example, a printed circuit board (PCB). The one or more solder balls 494 may be the only path for electrical current to flow in to or out of the circuit 400, for example, the only path by which electrical current may be received from the PCB and/or the only path by which electrical current may be transmitted to the PCB.

One or more conductive couplings 499 may be placed into contact with the one or more exposed portions of the first outer conductive layer 461 and/or the second outer conductive layer 462. As depicted in FIG. 4, the one or more conductive couplings 499 may be disposed on the first outer insulating layer 491 and placed into contact with one or more exposed portions of the first outer conductive layer 461. The one or more conductive couplings 499 may also be disposed on the second outer insulating layer 492 and placed into contact with one or more exposed portions of the second outer conductive layer 462. As will be understood from FIGS. 3A-3C, the one or more conductive couplings 499 may be analogous to the plurality of F2F couplings 341.

As will be understood from FIG. 4, the height of the one or more solder balls 494 may be selected so as to provide space for the second insulator 498, the one or more conductive couplings 499, and the components disposed between the second insulator 498 and the one or more conductive couplings 499.

In some implementations, the distance between the first outer conductive layer 461 and second outer conductive layer 462 may be selected to optimize mutual inductance between one or more inductors. As noted above, portions of the first outer conductive layer 461 and the second outer conductive layer 462 may take the shape of spiral inductors. For example, the first LB inductor 311b and/or the second LB inductor 311e depicted in FIGS. 3B-3C may be formed of the first outer conductive layer 461. Moreover, the first HB inductor 321b and/or the second HB inductor 321e may be formed of the second outer conductive layer 462.

As will be understood from FIG. 3A and FIG. 4, a pair of spiral inductors formed in parallel on the first outer conductive layer 461 and the second outer conductive layer 462, respectively, may demonstrate mutual inductance. The particular characteristics of the inductance may be based on a mutual inductance distance between the pair of parallel spiral inductors. In particular, the height of the one or more conductive couplings 499 may be selected to target a particular mutual inductance.

In some implementations, the respective heights of the first outer insulating layer 491 and the second outer insulating layer 492 may be known, and the space between the first outer insulating layer 491 and the second outer insulating layer 492 may be reducible to zero (such that the first outer insulating layer 491 and second outer insulating layer 492 are flush against one another). If the spacing between the first outer insulating layer 491 and the second outer insulating layer 492 is set to zero, then the pair of parallel spiral inductors in the circuit 400 may demonstrate mutual inductance having a first set of particular characteristics. If the particular characteristics are advantageous, then the one or more conductive couplings 499 may be configured to couple the first outer conductive layer 461 to the second outer conductive layer 462 such that the first outer insulating layer 491 is flush against the second outer insulating layer 492.

It will be understood that by selecting to increase the spacing between the first outer insulating layer 491 and the second outer insulating layer 492, the particular characteristics of the mutual inductance may be changed. Accordingly, the one or more conductive couplings 499 may be configured to couple the first outer conductive layer 461 to the second outer conductive layer 462 while maintaining a selected distance between the first outer insulating layer 491 and the second outer insulating layer 492, for example, a selected non-zero amount (as depicted in FIG. 4).

In other implementations, mutual inductance between pairs of parallel spiral inductors may not be preferred. Accordingly, the respective heights of the one or more conductive couplings 499 may be selected to be great enough that mutual inductance between pairs of parallel spiral inductors is zero and/or negligible.

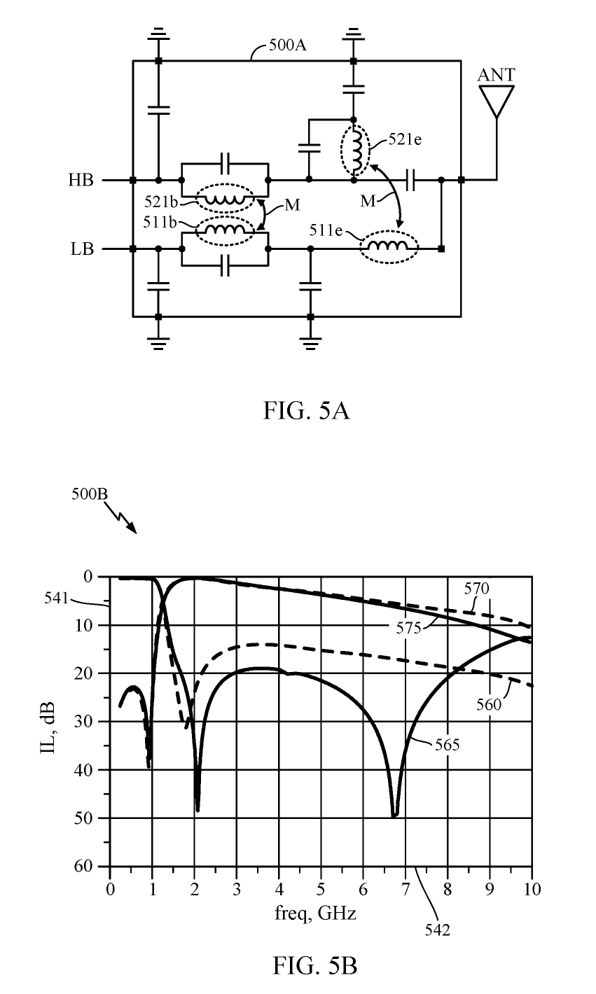

FIGS. 5A-5B generally illustrate the effects of mutual inductance in accordance with aspects of the disclosure.

FIG. 5A generally illustrates a schematic diagram of a circuit 500A in accordance with an aspect of the disclosure. The circuit 500A may be analogous to the circuit 100 depicted in FIG. 1. In particular, the circuit 500A may include a first LB inductor 511b analogous to the first LB inductor 111b, a second LB inductor 511e analogous to the second LB inductor 111e, a first HB inductor 521b analogous to the first HB inductor 121b, and a second HB inductor 521e analogous to the second HB inductor 121e.

Accordingly, the first LB inductor 511b and the first HB inductor 521b may be implemented as a first pair of parallel spiral inductors that demonstrate mutual inductance. Similarly, the second LB inductor 511e and the second HB inductor 521e may be implemented as a second pair of parallel spiral inductors that demonstrate mutual inductance.

The characteristics of the mutual inductance may depend on the physical distance between the pairs of parallel spiral inductors, as described above with respect to FIG. 4. The characteristics of the mutual inductance may also depend on whether the pairs of parallel spiral inductors are positively coupled or negatively coupled. Positive or negative coupling can be selected by reversing a direction of one of the spiral inductors, for example, by patterning one spiral inductor in a pair in a clockwise rather than a counterclockwise direction, or vice-versa.

FIG. 5B generally illustrates the effects of mutual inductance in the circuit 500A of FIG. 5A. The effects are illustrated in a graph 500B having a vertical axis 541 and a horizontal axis 542. The horizontal axis 542 shows frequency with a unit of gigahertz (GHz). The vertical axis 541 shows an example of a frequency response with a unit of decibels (dB) of the circuit 500A in accordance with aspects of the disclosure.

The graph 500B depicts a first LB frequency response 560 associated with a circuit arrangement in which there is no coupling between pairs of parallel spiral inductors. As will be understood from FIG. 5B, frequencies below approximately 1.0 GHz are associated with a frequency response of −0 dB, whereas frequencies above approximately 1.5 GHz are associated with a frequency response of at least −15 dB. However, the graph 500B also depicts a second LB frequency response 565 associated with a circuit arrangement in which there is coupling between pairs of parallel spiral inductors. As will be understood from FIG. 5B, the circuit 500A may still pass frequencies of 1.0 GHz or less with a frequency response of −0 dB, but rejection of higher frequencies may be improved due to the coupling. In particular, the second LB frequency response 565 demonstrates that the mutual inductance of a pair of parallel spiral inductors can perform as a notch filter, demonstrating notch filtering at frequencies of 2.0 GHz and 6.75 GHz.

It will be further understood that the notch filtering demonstrated by the second LB frequency response 565 can be obtained without significantly affecting the frequency response on the high band. As will be understood from FIG. 5B, the first HB frequency response 570, associated with a circuit arrangement of the circuit 500A in which there is no coupling, does not substantially differ from the second HB frequency response 575, associated with a circuit arrangement of the circuit 500A in which the aforementioned notch filtering is performed. Accordingly, a notch filter may be implemented on the low band without affecting performance on the high band.

The aforementioned notch filtering can be performed by selecting a design having negative coupling between the first LB inductor 511b and the first HB inductor 521b (for example, k=−0.5% for parallel spiral inductors at a distance of twenty micrometers) and a positive coupling between the second LB inductor 511e and the second HB inductor 521e (for example, k=+0.5% for parallel spiral inductors at a distance of twenty micrometers). However, it will be understood that the distance may be varied in accordance with aspects of the disclosure to obtain different results. Moreover, a design of the circuit 500A can be further varied by switching positive coupling (as between the second LB inductor 511e and the second HB inductor 521e) to negative coupling, or by switching negative coupling (as between the first LB inductor 511b and the first HB inductor 521b) to positive coupling. As noted above, this can be achieved by changing a clockwise spiral inductor of the pair of parallel spiral inductors to a counterclockwise spiral inductor, or vice-versa.

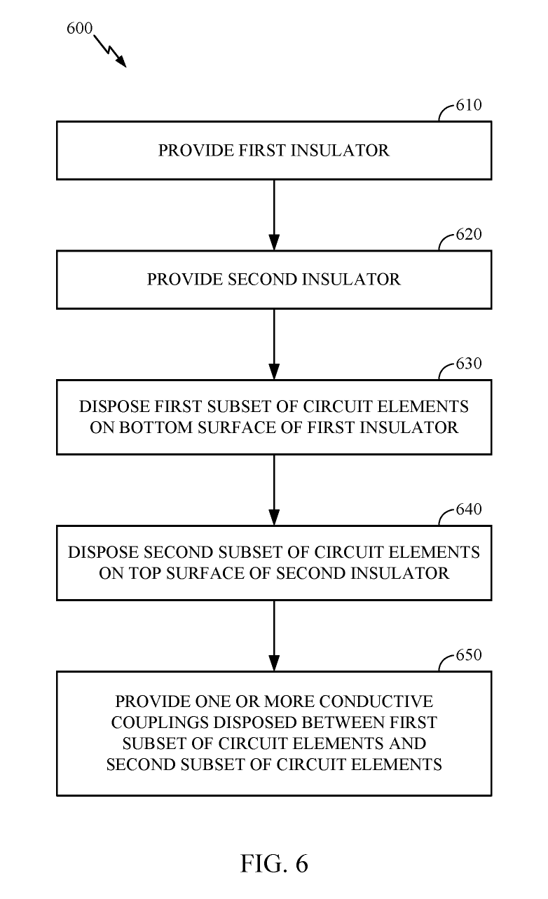

FIG. 6 is a flow diagram generally illustrating a method 600 for manufacturing a circuit having a F2F circuit layout in accordance with yet another aspect of the disclosure. The circuit may be, for example, a multiplexer. A circuit manufactured in accordance with the method 600 may be analogous to the any of the circuits depicted in FIG. 1, FIGS. 3A-3C, FIG. 4, and/or FIG. 5. However, the method 600 will be described as it would be performed to manufacture the circuit 400 depicted in FIG. 4.

At 610, the method 600 provides a first insulator. The first insulator provided at 610 may be analogous to the first insulator 497 depicted in FIG. 4. The first insulator provided at 610 may include, for example, glass.

At 620, the method 600 provides a second insulator. The second insulator provided at 620 may be analogous to the second insulator 498 depicted in FIG. 4. The second insulator provided at 620 may include, for example, glass.

In some implementations, the first insulator provided at 610 may be provided on a first panel upon which a plurality of insulators analogous to the first insulator are provided. Similarly, the second insulator provided at 620 may be provided on a second panel upon which a plurality of insulators analogous to the second insulator are provided. The first panel and/or the second panel may include a sheet of insulator, for example, a sheet of glass.

Although the providing at 610 and the providing at 620 are depicted in FIG. 6 as being performed in a particular order, it will be understood that the providing at 620 may be performed prior to or simultaneous with the providing at 610.

At 630, the method 600 disposes a first subset of circuit elements on a bottom surface of the first insulator provided at 610. The first subset of circuit elements may be analogous to the first subset of circuit elements 111 depicted in FIG. 1 and/or the first subset of circuit elements 311 depicted in FIG. 3C. Moreover, the first subset of circuit elements may be formed of various layers depicted in FIG. 4, for example, the first inner conductive layer 421, the first dielectric layer 431, the first middle conductive layer 441, the first middle insulator 445, the one or more first vias 451, the first outer conductive layer 461, or any combination thereof.

At 640, the method 600 disposes second first subset of circuit elements on a top surface of the second insulator provided at 620. The second subset of circuit elements may be analogous to the second subset of circuit elements 121 depicted in FIG. 1 and/or the second subset of circuit elements 321 depicted in FIG. 3B. Moreover, the second subset of circuit elements may be formed of various layers depicted in FIG. 4, for example, the second inner conductive layer 422, the second dielectric layer 432, the second middle conductive layer 442, the second middle insulator 446, the one or more second vias 452, the second outer conductive layer 462, or any combination thereof.

The disposing at 630 and/or the disposing at 640 may be performed, for example, by patterning and metallizing one or more conductive layers on a surface of a the first insulator provided at 610 and/or the second insulator provided at 620, respectively. The conductive layers may be analogous to the first inner conductive layer 421 and the second inner conductive layer 422 depicted in FIG. 4.

The disposing at 630 and/or the disposing at 640 may further include applying dielectric layers to inner conductive layers. The dielectric layers may be analogous to the first dielectric layer 431 and the second dielectric layer 432 depicted in FIG. 4.

The disposing at 630 and/or the disposing at 640 may further include patterning and metallizing middle conductive layers on the dielectric layers. The middle conductive layers may be analogous to the first middle conductive layer 441 and the second middle conductive layer 442 depicted in FIG. 4.

The disposing at 630 and/or the disposing at 640 may further include applying middle insulators to the inner conductive layers, dielectric layers, and/or middle conductive layers. The middle insulators may be analogous to the first middle insulator 445 and the second middle insulator 446 depicted in FIG. 4.

The disposing at 630 and/or the disposing at 640 may further include laser patterning vias in the middle insulators. The vias may be analogous to the one or more first vias 451 and the one or more second vias 452 depicted in FIG. 4. The vias may be filled with any suitable conductive material, for example, copper.

The disposing at 630 and/or the disposing at 640 may further include patterning and metallizing outer conductive layers on the one or more vias and/or the middle insulators. The outer conductive layers may be analogous to the first outer conductive layer 461 and the second outer conductive layer 462 depicted in FIG. 4. In some implementations, the outer conductive layers may include a plurality of sublayers. The plurality of sublayers may include conductive portions and insulative portions. The plurality of sublayer may facilitate formation of spiral shapes for inductors and may further facilitate electrical coupling of the spiral shapes to other components.

The disposing at 630 and/or the disposing at 640 may further include applying an insulative layer to the subset of circuit elements. The insulative layer may be analogous to the first outer insulating layer 491 and the second outer insulating layer 492 depicted in FIG. 4.

The disposing at 630 and/or the disposing at 640 may further include laser patterning vias in the insulative layer. The insulative layer may be analogous to the first outer insulating layer 491 and the second outer insulating layer 492 depicted in FIG. 4. The laser patterning may include exposing selected portions of the outer conductive layer that composes the subset of circuit elements. The vias may be filled with any suitable conductive material, for example, copper.

Although the disposing at 630 and the disposing at 640 are depicted in FIG. 6 as being performed in a particular order, it will be understood that the disposing at 640 may be performed prior to or simultaneous with the disposing at 630.

As noted above, in some implementations, the first insulator provided at 610 may be provided on a first panel and the second insulator provided at 620 may be provided on a second panel. Accordingly, the disposing at 630 may be performed with relation to the first panel and the disposing at 640 may be performed with relation to the second panel. After the disposing at 630 and/or disposing at 640 are performed, the method 600 may singulate the first panel and/or the second panel. The singulating may include slicing the panel to separate the plurality of circuits from one another.

At 650, the method 600 provides one or more conductive couplings disposed between the first subset of circuit elements and the second subset of circuit elements. The one or more conductive couplings provided at 650 may be analogous to the plurality of F2F couplings 341 depicted in FIGS. 3B-3C and/or the one or more conductive couplings 499 depicted in FIG. 4. The one or more conducive couplings provided at 650 may be implemented using any suitable material or technique, for example, flip-chip bumps, solder balls, etc.

In order to dispose the one or more conductive couplings between the first subset of circuit elements and the second subset of circuit elements, the method 600 may include providing the one or more conductive couplings on the first subset of circuit elements, aligning the first subset of circuit elements and the second subset of circuit elements, and coupling the one or more conductive couplings to the second subset of circuit elements. Alternatively, the method 600 may include providing the one or more conductive couplings on the second subset of circuit elements, aligning the first subset of circuit elements and the second subset of circuit elements, and coupling the one or more conductive couplings to the first subset of circuit elements.

The method 600 may further include providing one or more solder balls. The one or more solder balls may be analogous to the one or more solder balls 494 depicted in FIG. 4.

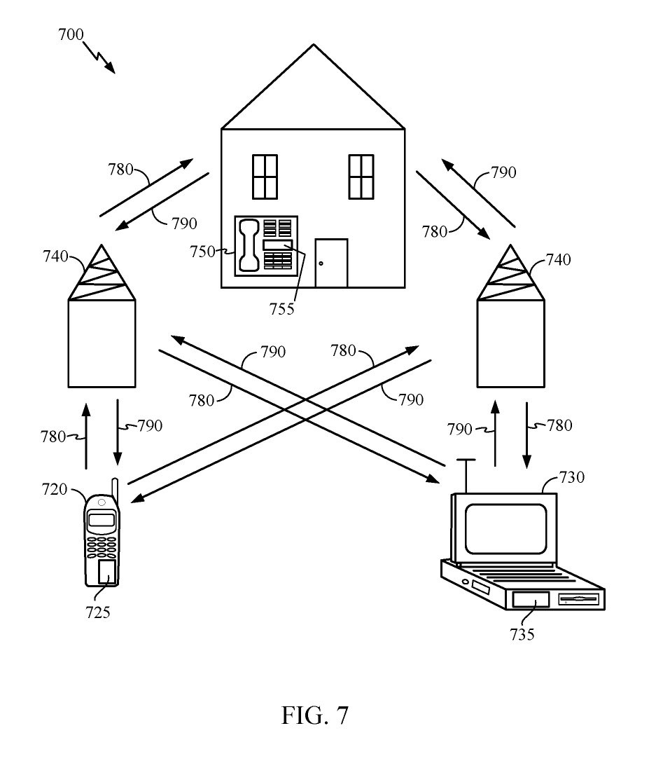

FIG. 7 is a block diagram showing an exemplary wireless communication system 700 in which an aspect of the disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include integrated circuit (IC) devices 725, 735 and 755, as disclosed below. It will be recognized that any device containing an IC may also include semiconductor components having the disclosed features and/or components manufactured by the processes disclosed here, including the base stations, switching devices, and network equipment. FIG. 7 shows forward link signals 780 from the base station 740 to the remote units 720, 730, and 750 and reverse link signals 790 from the remote units 720, 730, and 750 to base stations 740.

In FIG. 7, the remote unit 720 is shown as a mobile telephone, the remote unit 730 is shown as a portable computer, and the remote unit 750 is shown as a fixed location remote unit in a wireless local loop system. For example, the remote units may be a device such as a music player, a video player, an entertainment unit, a navigation device, a communications device, a personal digital assistant (PDA), a fixed location data unit, and a computer. Although FIG. 7 illustrates remote units according to the teachings of the disclosure, the disclosure is not limited to these exemplary illustrated units. The disclosure may be suitably employed in any device which includes semiconductor components, as described below.

The circuits disclosed herein may be included in a device such as a set top box, a music player, a video player, an entertainment unit, a navigation device, a communications device, a personal digital assistant (PDA), a fixed location data unit, or a computer.

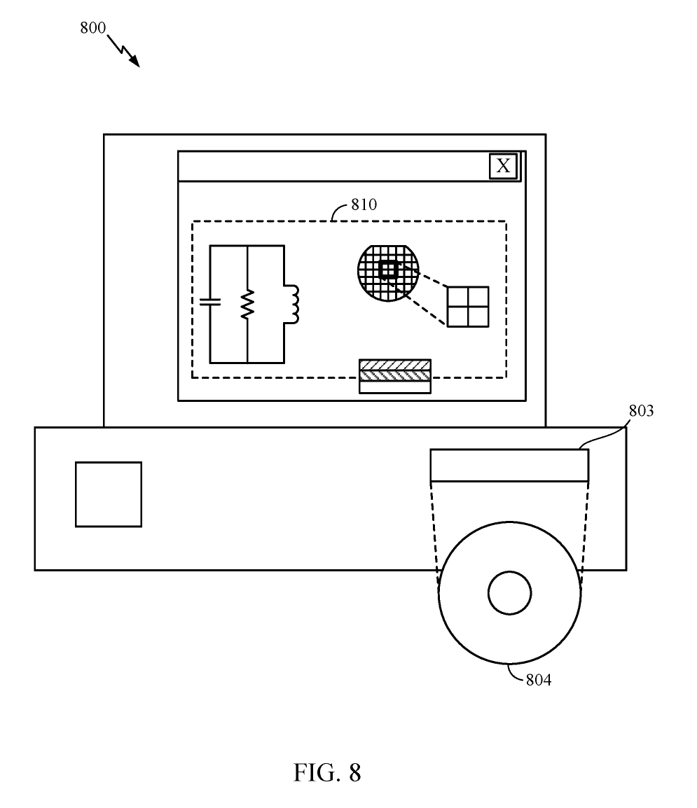

FIG. 8 is a block diagram illustrating a design workstation for circuit, layout, and design of a semiconductor part as disclosed herein. A design workstation 800 may include a hard disk containing operating system software, support files, and design software such as Cadence or OrCAD. The design workstation 800 also includes a display to facilitate design of a semiconductor part 810 that may include a circuit and semiconductor dies. A storage medium 804 is provided for tangibly storing the semiconductor part 810. The semiconductor part 810 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from, or writing output to, the storage medium 804.

Data recorded on the storage medium 804 may specify logic circuit configurations, pattern data for photolithography masks, or mask pattern data for serial write tools such as electron beam lithography. Providing data on the storage medium 804 facilitates the design of the semiconductor part 810 by decreasing the number of processes for designing circuits and semiconductor dies.

The foregoing description may have references to discrete elements or properties, such as a capacitor, capacitive, a resistor, resistive, an inductor, inductive, conductor, conductive, and the like. However, it will be appreciated that the various aspects disclosed herein are not limited to specific elements and that various components, elements, or portions of components or elements may be used to achieve the functionality of one or more discrete elements or properties. For example, a capacitive component or capacitive element may be a discrete device or may be formed by a specific arrangement of conductive traces separated by a dielectric material or combinations thereof. Likewise, an inductive component or inductive element may be a discrete device or may be formed by a specific arrangement of conductive traces and materials (e.g., air core, magnetic, paramagnetic, etc.) or combinations thereof. Similarly, a resistive component or resistive element may be a discrete device or may be formed by a semiconductor material, insulating material, adjusting the length and/or cross-sectional area of conductive traces, or combinations thereof. Moreover, a specific arrangement of conductive traces and materials may provide one or more resistive, capacitive, or inductive functions. Accordingly, it will be appreciated that the various components or elements disclosed herein are not limited to the specific aspects and or arrangements detailed, which are provided merely as illustrative examples.

While the foregoing disclosure shows illustrative aspects of the disclosure, it should be noted that various changes and modifications could be made herein without departing from the scope of the invention as defined by the appended claims. The functions, steps and/or actions of the method claims, in accordance with the aspects of the disclosure described herein, need not be performed in any particular order. Furthermore, although elements of the disclosure may be described or claimed in the singular, the plural is contemplated unless limitation to the singular is explicitly stated.

What is claimed is:

1. A circuit apparatus, comprising:
a first insulator;
a second insulator;
a first subset of circuit elements disposed on a bottom surface of the first insulator;
a second subset of circuit elements disposed on a top surface of the second insulator; and
one or more conductive couplings disposed between the first subset of circuit elements and the second subset of circuit elements.

2. The circuit apparatus of claim 1, wherein:
the one or more conductive couplings is a first set of one or more conductive couplings; and
the circuit apparatus further comprises:
a second set of one or more conductive couplings disposed on the first subset of circuit elements and configured to be coupled to a ball grid array perimeter array.

3. The circuit apparatus of claim 2, wherein the second set of one or more conductive couplings include:
a low-frequency band conductive coupling that is electrically coupled to the first subset of circuit elements;
a high-frequency band conductive coupling that is electrically coupled to the second subset of circuit elements; and
an antenna conductive coupling that is electrically coupled to one or more of the first subset of circuit elements and the second subset of circuit elements and configured to be electrically coupled to an antenna.

4. The circuit apparatus of claim 1, wherein the first insulator includes glass and the second insulator includes glass.

5. The circuit apparatus of claim 1, wherein:
the first subset of circuit elements includes a first inductor disposed on the bottom surface of the first insulator and a first capacitor disposed on the bottom surface of the first insulator; and
the second subset of circuit elements includes a second inductor disposed on the top surface of the second insulator having a lower inductance than the first inductor and a second capacitor disposed on the top surface of the second insulator having a lower capacitance than the first capacitor.

6. The circuit apparatus of claim 5, wherein the first inductor is a first spiral inductor and the second inductor is a second spiral inductor.

7. The circuit apparatus of claim 6, wherein the one or more conductive couplings have a selected height such that the first spiral inductor and the second spiral inductor are disposed in parallel at a distance relative to each other.

8. The circuit apparatus of claim 7, wherein the selected height is selected so that the first subset of circuit elements is configured to perform notch filtering.

9. The circuit apparatus of claim 8, wherein the notch filtering passes a first set of frequencies and rejects a second set of frequencies, wherein the second set of frequencies is higher than the first set of frequencies.

10. The circuit apparatus of claim 1, wherein at least one of the one or more conductive couplings is electrically coupled to a circuit element of the first subset of circuit elements and a circuit element of the second subset of circuit elements.

11. A method of manufacturing a circuit apparatus, the method comprising:
providing a first insulator;
providing a second insulator;
disposing a first subset of circuit elements on a bottom surface of the first insulator;
disposing a second subset of circuit elements on a top surface of the second insulator; and
providing one or more conductive couplings disposed between the first subset of circuit elements and the second subset of circuit elements.

12. The method of claim 11, wherein:
the one or more conductive couplings is a first set of one or more conductive couplings; and
the method further comprises:
providing a second set of one or more conductive couplings disposed on the first subset of circuit elements and configured to be coupled to a ball grid array perimeter array.

13. The method of claim 12, wherein the second set of one or more conductive couplings include:
a low-frequency band conductive coupling that is electrically coupled to the first subset of circuit elements;
a high-frequency band conductive coupling that is electrically coupled to the second subset of circuit elements; and
an antenna conductive coupling that is electrically coupled to one or more of the first subset of circuit elements and the second subset of circuit elements and configured to be electrically coupled to an antenna.

14. The method of claim 11, wherein the first insulator includes glass and the second insulator includes glass.

15. The method of claim 11, wherein:
disposing the first subset of circuit elements includes disposing a first inductor on the bottom surface of the first insulator and disposing a first capacitor on the bottom surface of the first insulator; and
disposing the second subset of circuit elements includes disposing a second inductor on the top surface of the second insulator having a lower inductance than the first inductor and disposing a second capacitor on the top surface of the second insulator having a lower capacitance than the first capacitor.

16. The method of claim 15, wherein disposing the first inductor comprises disposing a first spiral inductor and disposing the second inductor comprises disposing a second spiral inductor.

17. The method of claim 16, wherein providing the one or more conductive couplings disposed between the first subset of circuit elements and the second subset of circuit elements comprises providing one or more conductive couplings having a selected height such that the first spiral inductor and the second spiral inductor are disposed in parallel at a distance relative to each other.

18. The method of claim 17, wherein the selected height is selected so that the first subset of circuit elements is configured to perform notch filtering.

19. The method of claim 18, wherein the notch filtering passes a first set of frequencies and rejects a second set of frequencies, wherein the second set of frequencies is higher than the first set of frequencies.

20. The method of claim 11, wherein providing the one or more conductive couplings disposed between the first subset of circuit elements and the second subset of circuit elements comprises electrically coupling at least one of the one or more conductive couplings to a circuit element of the first subset of circuit elements and a circuit element of the second subset of circuit elements.
